(19) United States
(12) Patent Application Publication
(10) Pub. No.: US 2011/0108115 A1
(43) Pub. Date: May 12, 2011

(54) Forming a Photovoltaic Device

(75) Inventors: Hariklia Deligianni, Tenafly, NJ (US); Lubomyr T. Romankiw, Briancliff Manor, NY (US); Raman Vaidyanathan, Yonkers, NY (US)

(73) Assignee: International Business Machines Corporation, Armonk, NY (US)

(21) Appl. No.: 12/616,745

(22) Filed: Nov. 11, 2009

(51) Int. Cl. H01L 31/0296; H01L 31/18

(52) U.S. Cl. 136/262; 438/93; 257/E31.015

(57) ABSTRACT

Methods for forming photovoltaic devices, methods for forming semiconductor compounds, photovoltaic device and chemical solutions are presented. For example, a method for forming a photovoltaic device comprising a semiconductor layer includes forming the semiconductor layer by electrodeposition from an electrolyte solution. The electrolyte solution includes copper, indium, gallium, selenous acid (H₂SeO₃) and water.

### FIELD OF THE INVENTION

The present invention relates generally to photovoltaic devices formed by electrodeposition, and more particularly the invention relates to solar cells formed by electrodeposition of semiconductor compounds.

### BACKGROUND OF THE INVENTION

Electrodeposition can be used for relatively low cost deposition of thin film materials for photovoltaic applications. Cadmium telluride, copper indium di-selenide and copper indium gallium di-selenide are such materials and are used to make solar cells. Electrodeposition involves depositing from a solution, using electrical current, of a material onto a substrate. Electroplating and electrophoretic deposition are types of electrodeposition.

Solar cells convert light energy, such as sunlight, into electrical energy. One type of solar cell is fabricated from bulk or crystalline silicon. Crystalline silicon solar cells have a relatively high efficiency for conversion of light into electricity, but are relatively expensive to manufacture. Another type of solar cell is made from thin film semiconductors and, typically, is much less expensive to manufacture.

Semiconductor materials that are light absorbing materials are used in solar cells for absorbing light energy and converting the light energy into electricity. Semiconductor light absorbing materials having a wider bandgap typically convert more of the light impinging upon the material into electricity than do semiconductor materials having a lower bandgap.

### SUMMARY OF THE INVENTION

Principles of the invention provide, for example, methods for forming photovoltaic devices, methods for forming semiconductor compounds, photovoltaic devices, and chemical solutions.

In accordance with one aspect of the invention, a method for forming a photovoltaic device comprising a semiconductor layer includes forming the semiconductor layer by electrodeposition from an electrolyte solution. The electrolyte solution includes copper, indium, gallium, selenous acid (H₂SeO₃) and water.

In accordance with another aspect of the invention, a photovoltaic device includes a semiconductor layer formed by electrodeposition from an electrolyte solution. The electrolyte solution includes copper, indium, gallium, selenous acid (H₂SeO₃) and water.

In accordance with yet another aspect of the invention, a method for forming a semiconductor compound includes electrodeposition from an electrolyte solution. The electrolyte solution includes copper, indium, gallium, selenous acid (H₂SeO₃) and water.

In accordance with an additional aspect of the invention, a chemical solution comprises copper, indium, gallium, selenous acid (H₂SeO₃) and water.

A cupric salt, for example, cupric sulfate may comprise the copper. An indium salt (e.g., indium sulfate, indium chloride (e.g., InCl, InCl₂ or InCl₃), indium bromide (e.g., InBr₁ or InBr₃), indium iodide (e.g., InI), indium nitrate (InN₃O₉) or indium perchlorate) may, for example, comprise the indium. A gallium salt (e.g., gallium sulfate, gallium chloride (e.g., GaCl₂ or GaCl₃), gallium bromide (e.g., GaBr₃), gallium iodide (e.g., Ga₂I₆), gallium nitrate (GaN₃O₉) or gallium perchlorate) may, for example, comprise the gallium.

Aspects of the invention provide, for example, a low-cost method for forming thin film photovoltaic materials, such as thin film photovoltaic material used in solar cells. Principles of the invention provide, for example, chemical processes for incorporating gallium into electrodeposited materials, such as thin film photovoltaic materials. The incorporation of gallium into a photovoltaic material increases the bandgap of the material and improves the light energy to electrical energy conversion efficiency of solar cells made from the material.

These and other features, objects and advantages of the present invention will become apparent from the following detailed description of illustrative embodiments thereof, which is to be read in connection with the accompanying drawings.

### BRIEF DESCRIPTION OF THE DRAWINGS

FIG. 1 illustrates a solar cell comprising copper indium gallium di-selenide according to an embodiment of the invention.

FIG. 2 illustrates a method for forming a semiconductor compound according to an embodiment of the invention.

FIG. 3 is a scanning electron microscope image of a semiconductor layer formed according to an embodiment of the invention.

### DETAILED DESCRIPTION OF THE INVENTION

Principles of the present invention will be described herein in the context of illustrative methods for forming solar cells and semiconductor compounds. It is to be appreciated, however, that the techniques of the present invention are not limited to the specific method and devices shown and described herein. Rather, embodiments of the invention are directed broadly to techniques for electrodeposition of semiconductors and devices formed by the electrodeposition of the semiconductors. For this reason, numerous modifications can be made to the embodiments shown that are within the scope of the present invention. No limitations with respect to the specific embodiments described herein are intended or should be inferred.

Electrodeposition is a process of depositing one or more materials onto one or more substrate materials using electrical current. Electrodeposition processes include, for example, electroplating and electrophoretic deposition. For example, electrodeposition may use electrical current to reduce cations of a desired material from a solution (e.g., an electrolyte solution) and coat a conductive object (such as a metal or semiconductor) with a thin layer of the desired material. Electrodeposition may be used to foam thin film layers, for example, thin film semiconductor and/or metal layers in the formation of solar cells and other photovoltaic devices.

An electrolyte is a substance containing free ions that behaves as an electrically conductive medium. An electrolyte may consist of ions in solution which is referred to as an electrolyte solution or an ionic solution.

A thin film solar cell (TFSC), also called a thin film photovoltaic cell, is a solar cell that is made by depositing one or more thin layers (i.e., thin films) on a substrate. The thin films comprise, for example, photovoltaic materials such as copper indium di-selenide, copper gallium di-selenide and copper indium gallium di-selenide. Photovoltaic materials are materials that are used to convert light (e.g., sunlight) into electricity. The thicknesses of the thin films may, for example, vary from a nanometer, or less, to tens of micrometers. Thin film solar cells are usually categorized according to the photovoltaic material used. For example, thin film solar cells may comprise copper indium gallium di-selenide, copper indium di-selenide or copper gallium di-selenide. Other examples of thin film solar cells comprise silicon (Si), or cadmium telluride. An advantage of thin film solar cells as compared to crystalline solar cells (e.g., silicon crystalline solar cells) is that the thin film cells are typically less expensive to manufacture and may use less material (e.g., as low as 1% of the material in crystalline solar cells). However, for some TFSCs, the conversion efficiency for converting light (e.g., sunlight) to electricity has been shown to be less (e.g., up to about 20% for some copper indium gallium di-selenide solar cells) compared to crystalline silicon cells which can have conversion efficiencies up to about twenty-four percent.

A heterojunction, as used herein, is an interface between two layers or regions of dissimilar semiconductors, for example, semiconductors that have unequal band gaps. As used herein, the combination of multiple heterojunctions together in a device is called a heterostructure.

Copper indium di-selenide (CIS) is an I-III-VI₂ compound semiconductor material composed of copper, indium and selenium. CIS has a chemical formula of CuInSe₂ and may be used in, for example, thin film solar cells. CIS is also known as copper indium selenide.

Copper gallium di-selenide (CGS) is an I-III-VI₂ compound semiconductor material composed of copper, gallium and selenium. CGS has a chemical formula of CuGaSe₂ and may be used in, for example, thin film solar cells. CGS is also known as copper gallium selenide.

Copper indium gallium di-selenide (CIGS) is an I-III-VI₂ compound semiconductor material (e.g., a p-type semiconductor material). CIGS is also known as copper indium gallium selenide. In the broad sense, CIGS, as used herein, indicates a compound comprised of copper, indium, and either or both of gallium and selenium. That is, CIGS may be the compound CIS, the compound CGS or a compound containing all the elements copper, indium, gallium and selenium. CIGS may be a solid solution of the constituent elements of CIGS. CIGS has a chemical formula of CuInₓGa₍₁₋ₓ₎Se₂, where the value of X can vary from 1 (all CIS) to 0 (all CGS). CIGS is a tetrahedrally-bonded semiconductor, with a chalcopyrite crystal structure, and a bandgap varying continuously with X from about 1.0 eV (electron volts) at 300 K (degrees Kelvin) for CIS, to about 1.7 eV at 300 K for CGS. CIGS may be used, for example, as a light absorber material for thin film solar cells.

Copper indium gallium di-selenide solar cells (GIGS cells) are solar cells (e.g., thin film solar cells) comprising CIGS. For example, a CIGS cell may comprise a CIGS thin film, typically in the form of a polycrystalline thin film. Unlike a silicon solar cell based on a homojunction p-n junction, a structure of a CIGS cell is a more complex heterojunction structure or system. CIGS heterojunction cells have higher light to electricity conversion efficiencies than do many other thin film solar cells. An exemplary conversion efficiency of a CIGS heterojunction cell is about 19.9%. CIGS can be, for example, deposited directly onto a substrate (e.g., a molybdenum coated glass sheet) in polycrystalline form, thus avoiding the (energy) expensive step of growing large crystals as is necessary for solar cells made from crystalline silicon. Crystalline silicon cells typically comprise slices of solid silicon (e.g., silicon wafers), a more expensive semiconductor material.

According to methods of the invention, CIGS thin films may be formed by, for example, electrodeposition and annealing of the precursor material. Another method for forming CIGS films includes a vacuum-based process that co-evaporates or co-sputters copper, gallium, and indium. The resulting film may then be annealed with a selenide vapor to form a final CIGS thin film structure. An alternative method comprises directly co-evaporating copper, gallium, indium and selenium onto a heated substrate. A non-vacuum-based alternative process deposits nanoparticles of precursor materials onto a substrate and then sinters the nanoparticles in situ.

Zinc oxide has the chemical formula ZnO, is an inorganic compound and is an II-VI semiconductor. ZnO sometimes appears as a white powder and is nearly insoluble in water. ZnO is highly transparent and has high electron mobility. ZnO has a wide direct bandgap of about 3.3 electron volts (eV) at 300 K (E_{g,ZnO}=3.2 eV). The bandgap of ZnO can be increased by alloying the ZnO with magnesium oxide (MnO) or cadmium oxide (CdO). ZnO is usually of n-type character, even in the absence of intentional doping. Controllable n-type doping of ZnO is achieved by substituting Zn with group-III elements such as Aluminum, gallium or indium, or by substituting oxygen with group-VII elements chlorine or iodine.

A salt, as used herein, is an ionic compound comprising cations (positively charged ions) and anions (negative ions) so that the combination is electrically neutral. The component ions can be inorganic (e.g., chloride, Cl⁻), organic (e.g., acetate, CH₃COO⁻), monatomic ions (e.g., fluoride, F⁻), or polyatomic ions (e.g., sulfate, SO₄²⁻). Salt may result from, for example, the neutralization reaction of acids and bases. Salts that produce hydroxide ions (OH⁻) when dissolved in water are called basic salts. Salts that produce hydronium ions (H₃O⁺) in water are called acid salts. Neutral salts are those that are neither acid nor basic salts. The term sulfate refers to a salt of sulfuric acid. The term sulfonate refers to a salt or an ester of a sulfonic acid and contains the functional group R—SO₂O⁻. Examples of salts are: cupric sulfate, indium sulfate and gallium sulfate. Other salts (e.g., other salts comprising copper, indium or gallium) are contemplated including, but not limited to, salts comprising nitrogen (e.g., nitride ions, N³⁻), salts comprising chlorine (e.g., chloride ions, Cl⁻) or other halide ions, and perchlorates (e.g., salts comprising perchlorate ions, ClO₄⁻). Perchlorates are the salts derived from perchloric acid (HClO₄).

Cadmium sulfide is a chemical compound with the formula CdS. Cadmium sulfide is a direct bandgap semiconductor having a bandgap (E_{g}) of about 2.42 eV at 300 K (E_{g,CdS}=2.4 eV). CdS may be formed (e.g., grown) to be an n-type semiconductor. Alternately or additionally, CdS may be doped n-type by intentional inclusion of an n-type dopant (i.e., an additional material introduced into the semiconductor in very small concentrations to make the semiconductor n-type or more n-type).

Indium tin oxide (ITO) is a solid solution of indium(III) oxide (In₂O₃) and tin(IV) oxide (SnO₂), for example, 90% In₂O₃ and 10% SnO₂ by weight. ITO may also known as tin-doped indium oxide. ITO, therefore, comprises a metal, i.e., tin (Sn). ITO may be substantially transparent and substantially colorless in thin layers. In bulk form, ITO may be yellowish to grey. In the infrared region of the spectrum, ITO may be a metal-like mirror. A feature of ITO is a combination of electrical conductivity and optical transparency. However, high concentration of charge carriers will increase conductivity but decrease transparency. Thin films of indium tin oxide may be deposited on surfaces by electron beam evaporation, physical vapor deposition, or sputter deposition techniques. ITO may be used to make transparent conductive coatings for solar cells.

ITO is a semiconductor, as is indium oxide (i.e., indium(III) oxide, In₂O₃). Indium oxide, although a semiconductor, is not a particularly conducting material because indium oxide lacks free electrons. Free electrons may be added to indium oxide by doping with a similar element that has more electrons than does indium oxide, for example, tin. At low concentrations (e.g., below about 10% by weight), tin fits neatly into the indium oxide structure and adds the required electrons. ITO may comprise indium oxide doped with tin. ITO may be an n-type semiconductor.

The following elements may be represented by their chemical symbol as listed: aluminum—Al, copper—Cu, indium—In, selenium—Se, gallium—Ga and silver—Ag.

The following chemical compounds may be represented by their chemical formulas as indicated: copper indium—CuIn₂, copper indium gallium—CuInGa, copper gallium—CuGa₂, cupric sulfate or cupric sulfate—CuSO₄, indium sulfate—In₂(SO₄)₃, selenic acid—H₂SeO₄ or (HO)₂SeO₂, selenous acid or selenious acid—H₂SeO₃ or (HO)₂SeO, gallium sulfate—Ga₂(SO₄)₃, silver chloride—AgCl, and water—H₂O.

Sulfuric (or sulphuric) acid has the chemical formula H₂SO₄ and is a relatively strong acid. Sulfuric acid does not contain any carbon atoms and releases hydrogen ions when dissolved in water.

Sulfinic acids are oxoacids (i.e., an acid containing oxygen) of sulfur with the structure RSO(OH), where R is usually a hydrocarbon side chain. An example of a sulfinic acid is benzene sulfinic acid.

Benzene sulfinic acid is a sulfinic acid containing benzene and is represented by the formula C₆H₆O₂S.

Aliphatic chain amines include compounds such as ethylene diamine, ethylamine, dimethylamine, isooctylamine and many others of the same category.

Imidazoles are unsubstituted heterocyclic nitrogen compounds having at least two reactive nitrogen sites. Examples of imidazoles compounds are imidazole, tetrazole, 1,2,4 thiazole, 1,3,4 thiadiazole. Two or more of the imidazoles compounds polymerized together and with an amino group (amines) can form significant suppressors of the hydrogen evolution reaction.

Sulfonic acid, in general, refers to a member of the class of organic acids with the general formula R—S(═O)₂—OH, where R is usually a hydrocarbon side chain. The term sulfonic acid may also refer to a particular member of this class, namely the case where R=hydrogen. Sulfonic acids may be related to sulfuric acid, with one hydroxyl group removed. An example of a sulfonic acid is benzene sulfonic acid. Another example is methane sulfonic acid.

Benzene sulfonic acid is a sulfonic acid containing benzene and is represented by the formula C₆H₅SO₃H.

Methanesulfonic acid is a liquid with the chemical formula CH₃SO₃H and is an alkylsulfonic acid. Salts and esters of methanesulfonic acid are known as mesylates.

The term citrate may refer to the conjugate base of citric acid, i.e., C₃H₅O(COO)₃³⁻. Examples of citrates include monosodium citrate, disodium citrate and trisodium citrate. Alternately, citrate may refer to an ester of citric acid, for example, triethyl citrate.

Sodium citrate is a sodium salt of citric acid, for example, monosodium citrate having the chemical formula NaH(C₃H₅O(COO)₃, disodium citrate having the chemical formula Na₂H(C₃H₅O(COO)₃, and trisodium citrate having the chemical formula Na₃C₆H₅O₇. Sodium citrate is a chelating agent for the metallic species in solution. Other chelating agents that are used are carboxylic acids such as tartaric acid, malic acid and ethylene diamine tetraacetic acid (EDTA). Chelating or chelation is the formation or presence of two or more separate bindings between a polydentate ligand and a single central atom. Usually these ligands are organic compounds, and are called chelating agents. Chelating agents are chemicals that form soluble, complex molecules with certain metal ions, inactivating the ions so that they cannot normally react with other elements or ions to produce precipitates or scale.

Sodium hydroxide is a metallic base having the chemical formula NaOH.

Grain refiners are additives (e.g., solute particles) that can be added to a solution limiting the growth of crystal dendrites. Grain refiners assist in controlling grain size, in grain refinement, and in strengthening of grain boundaries.

An alcohol is any organic compound in which a hydroxyl group (—OH) is bound to a carbon atom of an alkyl or substituted alkyl group. Sorbitol and mannitol are examples of an alcohol.

Sorbitol, also known as glucitol, is a sugar alcohol having the chemical formula C₆H₁₄O₆. Mammitol is another sugar alcohol. Sorbitol, glucitol and mannitol alcohols are used as grain refiners in high pH solutions (e.g., basic solutions).

A bandgap (also called an energy gap) of a material, is an energy range of the material where no electron states exist. For insulators and semiconductors, the bandgap generally refers to the energy difference between the top of the valence band of the material and the bottom of the conduction band of the material. The bandgap is the amount of energy required to free an outer-shell electron from its orbit about the nucleus to a free state. Bandgaps are usually expressed in electron volts

A reference electrode is an electrode which typically has a stable and well-known electrode potential. The high stability of the electrode potential is usually reached by employing, for example, a redox system with constant (e.g., buffered or saturated) concentrations of each participants of the redox reaction. There are many ways reference electrodes are used, for example, as a half cell to build an electrochemical cell. This allows the potential of the other half cell, within the electrochemical cell, to be determined. A saturated calomel electrode and an Ag/AgCl electrode are examples of aqueous reference electrodes.

A saturated calomel electrode (SCE) is a reference electrode based on the reaction between elemental mercury (Hg) and mercury(I) chloride (Hg₂Cl₂), also known as calomel). The SCE is used, for example, in electrochemistry. An aqueous phase in contact with the mercury and the mercury(I) chloride may be a saturated solution of potassium chloride (KCl) in water. The electrode is linked, for example, via a porous frit (e.g., a salt bridge) to the solution in which another electrode (e.g. an electrode of a half-cell other that the half cell comprising the SCE) is immersed. A frit may be a ceramic composition that has been fused, quenched to form a glass, and granulated. A salt bridge may be a laboratory device used to connect oxidation and reduction half-cells of a galvanic or voltaic cell, which is a type of electrochemical cell.

A silver/silver chloride (Ag/AgCl), mercury/mercury chloride (Hg/Hg₂Cl₂) (SCE), mercury/mercury sulfate (Hg/HgSO₄) (molten salt electrolyte, MSE) or solid wire electrodes may also be used as reference electrodes.

A unit of measure M represents a molar concentration or molarity and indicates an amount of solute per unit volume of solution. One (1) M=1 mole of solute per liter of solution. One (1) mM=0.001 moles of solute per liter of solution. For example, a solution containing 0.005 moles of CuSO₄ per liter of solution is expressed as 5 mM CuSO₄. When molar concentrations are indicated herein, the con stated concentrations are considered to be approximate, for example, the concentrations may be considered to be within plus and minus ten percent. For example, if a molarity is expressed as ten one-thousands (0.010) of a mole of solute per liter of solution, the intended molarity may be considered to be from about 0.009 to about 0.011 of a mole of solute per liter of solution.

pH is a measure of the acidity of a solution, and is measured using a pH scale. The pH scale corresponds to the concentration of hydronium ions (H₃O⁺) in the solution. The exponent of the H₃O⁺ concentration, after removal of any negative sign, is the pH of a solution. For example, in pure water, the concentration of hydronium ions is 1×10⁻⁷ M. Thus, the pH of a solution of pure water is 7. The pH scale ranges from 0 to 14, where 7 is considered neutral (i.e., the concentration of H₃O⁺ equals the concentration of OH⁻), below 7 acidic and above 7 basic. The further from 7 the pH is on the pH scale, the more acidic or basic the solution is. For example, a solution with a pH=1 has a hydronium ion concentration of 1×10⁻¹ M (0.1 M or 100 mM).

The term proximate or proximate to, as used herein, has meaning inclusive of, but not limited to, abutting, in contact with, and operatively in contact with. In particular and with respect to conductors and/or semiconductors, proximate, or proximate to, may include, but is not limited to, being electrically coupled or coupled to. The term abut(s) or abutting, as used herein, has meaning that includes, but is not limited to, being proximate to.

Electrodeposition is, for example, a low cost deposition method for thin film photovoltaic materials such as CIGS and cadmium telluride (CdTe). However, a big challenge lies in the design of the chemistry and the incorporation of indium and gallium in the electrodeposited materials such as CIS, CIGS and CGS. Gallium may be included in thin film solar cell because gallium can increase the bandgap of a semiconductor light absorber material such as CIS and CIGS. Gallium, therefore, may contribute to increased solar cell efficiency.

Hydrogen evolution is a process of generating or forming of hydrogen molecules or ions. Hydrogen evolution may occur simultaneously with metal or semiconductor electrodeposition and reduces current used for the semiconductor electrodeposition. In this way, hydrogen evolution may interfere with semiconductor electrodeposition. In general, hydrogen evolution is enhanced in solutions that are acidic rather than solutions that are basic. There are particular organic additives that inhibit hydrogen evolution, for example, sulfur and nitrogen bearing organic compounds.

A principle of the invention is deposition of compounds containing indium (e.g., CIS and CIGS but excluding CGS). If the pH at the surface during deposition rises to above about 3 to 4, indium and gallium oxide (e.g., indium and gallium hydroxide) may be deposited in addition to or in place of CIS or CIGS, and hydrogen evolution occurs at a high rate. Blocking hydrogen evolution enables or enhances the deposition of CIS and/or CIGS and improves the morphology of the CIS/CIGS deposit.

The addition of hydrogen suppressor additives, for example, sodium monohydrogen phthalate, monosodium phosphate, glycine, barbital, sorbitol, mannitol, a sulfinic acid, a sulfonic acid, other sulfinic or sulfonic compounds (e.g., benzene sulfonic compounds and benzene sulfinic compounds), amines, imidazoles and imidazole polymeric compounds (polymers), may block or reduce hydrogen evolution. Sulfinic and sulfonic acids include, but are not limited to, benzene sulfinic acid and benzene sulfonic acid. This principle of the invention is associated with, for example, the third aspect and the third exemplary method of the invention, both described below. In one embodiment of the invention, moderate temperatures (e.g., about 25 to 90° C.) are used in conjunction with a hydrogen evolution suppressor additive.

Another principle of the invention is the deposition of compounds containing gallium (e.g., CGS and CIGS but excluding CIS). In a certain embodiment of the invention, the deposition of compounds containing gallium is enabled or enhanced by deposition from an acidic solution and by the addition of sulfinic acid to the solution to block or reduce hydrogen evolution. This embodiment is associated with, for example, the first aspect and the first exemplary method of the invention, both described below. In another embodiment of the invention, the deposition of compounds containing gallium is enabled or enhanced by deposition from a basic solution (e.g., a solution having a pH of about 9 or higher). The basic nature of the solution assists in the dissolution of compounds containing gallium as well as compounds containing copper and indium. Because the solution is basic, the hydrogen evolution rate is low (e.g., suppressed). This embodiment is associated with, for example, the fourth aspect and the fourth exemplary method of the invention, both described below.

A first aspect of the invention is an electrodeposition method using an acidic aqueous solution with a pH low enough to dissolve (e.g., assists in dissolution of) compounds (e.g., salts or acids) containing Cu, In, Se and Ga, and electrodeposit CIS, CGS, CuIn₂, CIGS, CuGa₂ or CuGaSe₂. For example, a pH lower than about 2.5 (e.g., from a pH of about 0 to a pH of about 2.5) may be low enough to dissolve the desired compound(s). For example, the compounds CIS, CGS, CuIn₂, CIGS, CuInGa, CuGa₂, CuGaSe₂ may be electrodeposited with this electrodeposition method.

A second aspect of the invention is an electrodeposition method using moderate to relatively high temperature for electrodeposition in an aqueous solution. The moderate to relatively high temperature improves or assists in the solubility of gallium containing compounds (e.g., gallium salts) in the aqueous solution. For example, a temperature range of about 25 to about 90 degrees Celsius (° C.) may be used. In aqueous mildly acidic solutions, a low cupric ion concentration, with respect to the other species in solution, may be needed to ascertain that copper is incorporated at the diffusion limit and to obtain a copper-poor or copper-depleted CIGS compound or alloy. For example, the compounds CIS, CGS, CuIn₂, CIGS, CuInGa, CuGa₂, CuGaSe₂ may be electrodeposited with this electrodeposition method.

A third aspect of the invention is another electrodeposition method using a methanesulfonic acid/water based chemistry that allows, enhances or assists in dissolution of components including, for example, those compounds (e.g., salts or acids) containing copper, indium, selenium and gallium. Use of organic additives in the acid chemistry substantially suppresses hydrogen evolution during electrodeposition. For example, the compounds CIS, CGS, CuIn₂, CIGS, CuInGa, CuGa₂, CuGaSe₂ may be electrodeposited with this electrodeposition method.

A fourth aspect of the invention is an additional electrodeposition method using a basic aqueous solution with a pH high enough to dissolve (e.g., assists in dissolution of) compounds (e.g., salts or acids) containing copper, indium, selenium and gallium, and electrodeposit CIS, CGS, CuIn₂, CIGS, CuGa₂ and CuGaSe₂. For example, a pH higher than about 8 (e.g., a pH of about 10 or higher) may be high enough to dissolve the desired compound(s). Grain refiners, for example, sorbitol, mammitol and other organic alcohols may be used. For example, the compounds CIS, CGS, CuIn₂, CIGS, CuInGa, CuGa₂, CuGaSe₂ may be electrodeposited with this electrodeposition method.

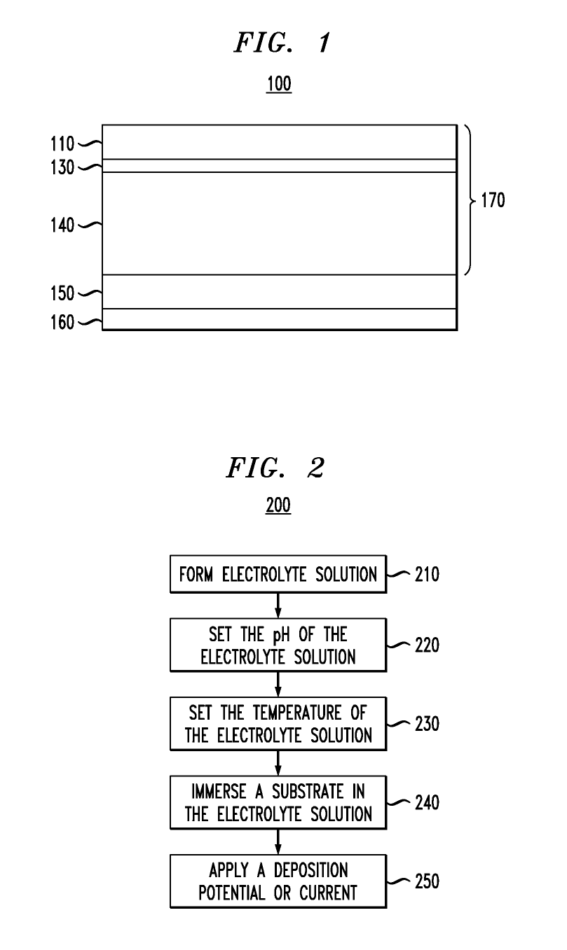

FIG. 1 illustrates a thin film solar cell (i.e., a photovoltaic device) 100 comprising CIGS, according to an embodiment of the invention. For example, the solar cell 100 may be formed according to method 200 or the first, second, third or fourth exemplary methods described below. The thin film solar cell 100 comprises CIGS, a semiconductor light absorbing material having a direct bandgap. As mentioned above, the term CIGS (CuInₓGa₍₁₋ₓ₎Se₂), as used herein, is a compound comprised of copper, indium, and either or both of gallium and selenium. In the broad sense, at one extreme CIGS may be the compound CIS that does not comprise gallium (X=1); at the other extreme CIGS may be the compound CGS that does not comprise indium (X=0); or CIGS may be a compound containing all of the elements: copper, indium, gallium and selenium (X is between 0 and 1, but not including 0 and 1). Also, as mentioned above, CIGS (CuInₓGa₍₁₋ₓ₎Se₂) has a bandgap varying continuously with X from about 1.0 eV (electron volts) at 300 K (degrees Kelvin) for CIS (X=1), to about 1.7 eV at 300 K for CGS (X=0).

The cell 100 comprises a substrate 160, a back contact layer 150 and a heterostructure 170. The substrate 160 is a layer upon or above which the other layers of cell 100 are formed. The substrate may provide mechanical support for cell 100. An exemplary substrate 160 comprises a soda-lime glass having a thickness of about one to three millimeters (mm). Other exemplary substrates include other glasses, metal (e.g., metal foil) and plastic.

A back contact 150 is a layer formed upon the substrate and therefore abuts or is proximate to the substrate 160. The back contact 150 is typically a metal and may comprise, for example, molybdenum (Mo). Alternately or additionally, the back contact 150 may comprise a semiconductor. The back contact 150 is an electrical contact that provides back-side electrical contact to provide current from the cell 100. An Exemplary back contact 150 is a layer having a thickness from about 0.5 micron to about 1 micron.

The heterostructure 170 abuts or is proximate to the back contact 150 and comprises a first semiconductor layer 140, a second semiconductor layer 130 and a third semiconductor layer 110.

The first semiconductor layer 140 is a light absorbing layer comprising CIGS, and may be, for example, about 1 to about 2 microns thick. The CIGS comprised within first semiconductor layer 140 may be, for example, nanocrystalline (microcrystalline) or polycrystalline and may be formed p-type, for example, formed p-type from intrinsic defects within the CIGS. Nanocrystalline and polycrystalline CIGS both comprise crystalline grains, but differ in, for example, the grain size of the crystalline grains. Alternately or additionally, the CIGS may be formed p-type by intentional inclusion (e.g., doping) of a p-type dopant (i.e., an additional material introduced into the CIGS in very small concentrations to make the CIGS semiconductor p-type or more p-type).

The second semiconductor layer 130 may comprise, for example, an approximately 0.7 microns thick layer of n-type CdS. The second semiconductor layer 130 is formed upon and abuts or is proximate to the first semiconductor layer 140.

The third semiconductor layer 110, besides being part of the heterostructure 170, may provide front-side electrical contact to provide current from the cell 100. The third semiconductor layer 110 comprises, for example, a zinc oxide layer formed upon and abuts the second semiconductor layer 140. The third semiconductor layer 110 layer may alternately or additionally comprise ITO. The third semiconductor layer 110 may be, for example, about 2.5 microns thick. The third semiconductor layer 110 is formed upon and abuts or is proximate to the second semiconductor layer 130.

Thus, the heterostructure 170 comprises two heterojunctions, a first heterojunction between the first semiconductor layer 140 and the second semiconductor layer 130, and a second heterojunction between the second semiconductor layer 130 and the third semiconductor layer 110. The first heterojunction is a p/n junction between p-type CGIS and n-type CdS. The second heterojunction is an n/n junction between n-type CdS and the n-type third semiconductor layer 110. Typically, the second semiconductor layer 130 and possibly the third semiconductor layer 110 are more heavily doped (e.g., dopant per cubic centimeter of material being doped), than the first semiconductor layer 140 is doped. This asymmetric doping between the CIGS of the first semiconductor layer 140 and the CdS of the second semiconductor layer 130 causes a space-charge region to extend much further into the first semiconductor layer 110 than into the second semiconductor layer 130.

The first semiconductor layer 140 comprising the CIGS semiconductor material having a bandgap between 1.0 eV and 1.7 eV and acting as a light absorber. Absorption is minimized in the second semiconductor layer 130, and in the third semiconductor layer 110 by, for example, the choice of larger bandgap materials for these layers (E_{g,ZnO}=˜3.2 eV, E_{g,Cds}=˜2.4 eV, and E_{g,ITO}>˜3.5 eV; ˜ indicates approximate).

In one embodiment of the invention, the first semiconductor layer 140 may comprise a composition-graded material having a bandgap that changes with the composition. For example, 140 may comprise CIGS having a higher concentration of gallium, corresponding to a larger bandgap, near the top and a lower concentration of gallium, corresponding to a smaller bandgap, near the bottom. Between the top and the bottom, the concentration of gallium may be graded between the concentration at the top and the concentration at the bottom providing a corresponding grading of the bandgap between the bandgap at the top and the bandgap at the bottom. A solar cell having such a graded composition may, for example, provide higher conversion efficiency, due to absorption of a wider spectrum of light, than a similar solar cell not having the grading of the composition. This, for example, can be accomplished either by applying a different potential or current in the same electroplating solution or by depositing from two different solutions CIGS followed by CuGaSe₂ (CGS). When applying a different potential or current it is possible to deposit different composition materials for example first CuInSe₂ and then CuInGaSe₂.

The cell 100 may comprise additional layers or structures not shown in FIG. 1, for examples, a metallic grid (e.g., a nickel and/or aluminum-grid) deposited or formed onto the top of the third semiconductor layer 110 to form an electrical contact to provide current produced from the cell 100, and an encapsulation.

FIG. 2 illustrates a method 200 for forming a semiconductor compound, according to an embodiment of the invention. The semiconductor compound may be comprised within a solar cell, for example, the solar cell 100 of FIG. 1. Therefore, method 200 may also be considered as a method for forming a solar cell, for example, the solar cell 100 of FIG. 1. Method 200 farms the semiconductor compound by electrodeposition of, for example, one or more thin films of CIGS (including CIS or CGS).

Step 210 of method 200 comprises forming the electrolyte solution. The electrolyte solution may be formed by, for example, dissolving one or more solutes in a solvent. The one or more solutes comprise copper, indium and/or gallium. The copper, indium and/or gallium may be comprised within compounds, for example, salts, for example, cupric sulfate, indium sulfate and gallium sulfate, or other indium or gallium salts), or may be comprised within other compounds. Other exemplary salts of indium and gallium that may be used are indium chloride (e.g., InCl, InCl₂ and InCl₃), indium bromide (e.g., InBr₁ and InBr₃), indium iodide (e.g., InI), indium nitrate (InN₃O₉), indium perchlorate, gallium chloride (e.g., GaCl₂ and GaCl₃), gallium bromide (e.g., GaBr₃), gallium iodide (e.g., Ga₂I₆), gallium nitrate (GaN₃O₉) and gallium perchlorate. The electrolyte solution may further comprise, but does not have to comprise, a chelating agent.

The one or more solutes may comprise, for example, cupric sulfate, indium sulfate, gallium sulfate, selenous acid, a sodium citrate (e.g., trisodium citrate), copper methanesulfonate, sorbitol, mammitol, alcohol and/or sulfuric acid. By way of example only, the solvent may comprise one or more of water, sodium hydroxide, sulfuric acid, methanesulfonic acid. The assignment of compounds or elements to the classes of solute and solvents is somewhat arbitrary. For example, sodium hydroxide, sulfuric acid, methanesulfonic acid could alternately be considered solutes dissolved in the solvent water.

Step 220 comprises adjusting or setting the pH of the electrolyte solution to a desired, useful or optimal pH for the electrodeposition. By way of a first example, the pH is adjusted or set low enough to dissolve compounds containing one or more of copper, indium, selenium and gallium, and electrodeposit CIGS (including CIS and CGS). For example, the pH may be set to a pH lower than about 2.5 to assist in the dissolution of the compounds containing the one or more of copper, indium, selenium and gallium. In this case, the pH may be adjusted by adding sulfuric acid to the electrolyte solution. By way of a second example, the pH is adjusted or set high enough to dissolve compounds containing one or more of copper, indium, selenium and gallium, and electrodeposit CIGS (including CIS and CGS). For example, the pH may be set to a pH higher than about 8 to assist in the dissolution of the compounds containing the one or more of copper, indium, selenium and gallium. In this case, the pH may be adjusted by adding sodium hydroxide to the electrolyte solution.

Step 230 comprises adjusting or setting the temperature of the electrolyte solution to a desired, useful or optimal temperature for the electrodeposition. By way of example only, the temperature is set high enough for electrodeposition in an aqueous solution, such that the temperature improves, or assists in, the solubility of gallium containing compounds (e.g., gallium salts) in the aqueous solution. For example, a temperature range of about 20 or about 25 to about 90 degrees Celsius (° C.) may be used. Temperatures within this range, especially at about 70° C. and higher improves the crystalline structure of the deposited material, for example, the grain size of crystalline grains is made larger.

Step 240 comprises immersing the material being deposited upon (e.g., a substrate, a semiconductor layer or thin film, or a metallic thin film) in the electrolyte solution.

Step 250 comprises applying a deposition potential or a deposition current (e.g., current density, for example, as expressed by milliamperes/cm²), to assist in the electrodeposition. For example, the deposition potential or current may be applied between a substrate upon which the material is being deposited and a reference electrode. The reference electrode is, for example, immersed in or in physical contact with the electrolyte solution. Exemplary deposition currents comprise current densities from about (i.e., within 10% of) 5 to about 20 milliampers/cm2 of deposited material. The magnitude of the potential or current determines the composition of the thin film being deposited. As an example, depending upon the applied potential or current, a film containing varying amounts of indium and gallium may be formed. At relatively low deposition potentials or currents, films containing little or no gallium may be foamed, for example, CIS may be formed. At relatively high deposition potentials or currents, films containing little or no indium may be formed, for example, CGS may be formed. At intermediate potentials or currents, films containing both indium and gallium may be formed, for example, CIGS comprising both gallium and indium may be formed. The amounts of indium and gallium comprised in the CIGS film may be determined by the potential or current. The deposition potential or current may be applied until the desired thickness or amount of the deposited material is achieved. The deposition potential or current may be varied during deposition to deposit material having a change in composition with depth of composition. An example is the deposition of a CIGS layer having a gallium concentration that changes during the deposition as the deposition potential or current is changed during the deposition.

Four exemplary methods for electrodeposition of CIGS are described below. The four exemplary methods use one or more steps of method 200 and may be used to form a photovoltaic device (e.g., solar cell 100) according to embodiments of the invention.

A first exemplary method, according to an embodiment of the invention, comprises electrodeposition of CIGS (including CIS and/or CGS) from an aqueous sulfate electrolyte containing 5 mM cupric sulfate (CuSO₄), 10 mM indium sulfate (In₂(SO₄)₃), 10 mM selenous acid (H₂SeO₃) and 10 mM gallium sulfate (Ga₂(SO₄)₃). The pH of the solution is set and maintained less than about 2.5, for example, between a pH of approximately 1 and a pH of approximately 2 by adding sulfuric acid (H₂SO₄) to the solution. During electrodeposition the temperature is set and maintained at about 70° C. (e.g., within 7° C. of 70° C.). The first exemplary method of the invention is associated with, for example, the first aspect of the invention described above. Hydrogen evolution may be suppressed by adding sulfinic or sulfonic compounds or aliphatic chain amines include compounds such as ethylene diamine, ethylamine, dimethylamine, isooctylamine or imidazoles such as imidazole, tetrazole, 1,2,4 thiazole, 1,3,4 thiadiazole. Two or more of the compounds polymerized together and with an amino group can form improved suppressors of the hydrogen evolution reaction.

At low deposition potentials (e.g., cathodic potentials), applied between the electrolyte solution and a material being deposited upon (e.g., a substrate, another semiconductor layer or thin film, or a metallic thin film) with magnitudes below about 900 millivolts (mV) (e.g., in the range of about −600 mV to about −900 mV, versus the Ag/AgCl electrode), a copper rich phase of CIS <112> is formed. At potentials with magnitudes higher than about 900 mV (e.g., in the range of about −900 mV to about −1.3 V, versus the Ag/AgCl electrode) copper-depleted CIGS is formed, for example, CIGS comprising both indium and gallium.

Consider the formula for CIGS, CuInₓGa₍₁₋ₓ₎Se₂, as representing a composition of a semiconductor compound comprising copper and selenium. Cu represents the copper, In represents indium, Ga represents gallium, and Se represents the selenium. CIS is represented by CuInSe₂, and CGS is represented by CuGaSe₂. If X equals 1, the formula CuInₓGa₍₁₋ₓ₎Se₂ degenerates to CuInSe₂, and the semiconductor compound includes only CIS, not any gallium or CGS, that is, all of the copper in the semiconductor compound is that copper within CIS. If X equals 0, the formula CuInₓGa₍₁₋ₓ₎Se₂ degenerates to CuGaSe₂, and the semiconductor compound includes only CGS, not any indium or any CIS, that is, all of the copper in the semiconductor compound is that copper within CGS. If X has a value between 0 and 1, the semiconductor compound comprises CIGS comprising both indium and gallium having a ratio of an amount of indium to an amount of gallium equal to a ratio of X to 1−X. X may decrease as the magnitude of the potential increases above 900 millivolts.

A solar cell (e.g., a thin film solar cell) may be formed to include one or more semiconductors formed according the first exemplary method.

A second exemplary method, according to an embodiment of the invention, comprises electrodeposition of CIGS (including CIS and/or CGS) from an aqueous citrate electrolyte containing 1 to 5 mM cupric sulfate (CuSO₄), 5 to 50 mM indium sulfate (In₂(SO₄)₃), 5 to 50 mM selenous acid (H₂SeO₃), 5 to 50 mM gallium sulfate (Ga₂(SO₄)₃) and 0.2 M trisodium citrate (Na₃C₆H₅O₇). The molar ratio between the dissolved species in solution is typically Cu:In:Se:Ga (1:3:3:3). The solution pH is set and maintained at approximately 2.5 by adding H₂SO₄ as needed. The temperature is set and maintained at or between approximately 25° C. and approximately 90° C. (e.g., at or between approximately 55° C. and approximately 75° C.). Temperatures at or between about 55° C. and about 75° C. may be high enough to enhance the solubility of the gallium sulfate (e.g., assist in dissolving the gallium sulfate). The second exemplary method of the invention is associated with, for example, the second aspect of the invention described above. At low deposition potentials (e.g., cathodic potentials), applied between the electrolyte solution and a material being deposited upon (e.g., a substrate, another semiconductor layer or thin film, or a metallic thin film) with magnitudes below about 1 volts (V) (e.g., about −0.8 to about −1 V, versus the SCE) CIS <112> is formed, while at higher potentials with magnitudes higher than about 1 V (e.g., over-potentials; about −1.3V, versus the SCE) CIGS is formed.

Consider the formula for CIGS, CuInₓGa₍₁₋ₓ₎Se₂, as representing a composition of a semiconductor compound containing copper and selenium. Cu represents the copper, In represents indium, Ga represents gallium and Se represents the selenium. CIS is represented by CuInSe₂, and CGS is represented by CuGaSe₂. If X equals 1, the formula CuInₓGa₍₁₋ₓ₎Se₂ degenerates to CuInSe₂, and the semiconductor compound includes only CIS, not any gallium or any CGS, that is, all of the copper in the semiconductor compound is that copper within CIS. If X equals 0, the formula CuInₓGa₍₁₋ₓ₎Se₂ degenerates to CuGaSe₂, and the semiconductor compound includes only CGS, not any indium or any CIS, that is, all of the copper in the semiconductor compound is that copper within CGS. If X has a value between 0 and 1, the semiconductor compound comprises CIGS comprising both indium and gallium having a ratio of an amount of indium to an amount of gallium equal to a ratio of X to 1-X. X decreases as the magnitude of the potential increases above about 1 volt.

A solar cell (e.g., a thin film solar cell) may be formed to include one or more semiconductors formed according the second exemplary method.

A third exemplary method, according to an embodiment of the invention, uses a methanesulfonic acid chemistry for electrodeposition of CIGS, CIS or CGS. All the species of 10 mM copper sulfate, 50 mM indium sulfate, 50 mM gallium sulfate and 50 mM selenous acid (H₂SeO₃) are dissolved in a 1 M methanesulfonic acid (CH₃SO₃H) solution in water. Other copper, indium and gallium salts may be used instead of the copper sulfate. Methanesulfonic acid solutions allow for a unique resistance to the oxidation of metal ions to their higher valence state. For example, the selenium species have multiple oxidation states of +8, +6 +4. Because the methanesulfonic acid chemistry is very acidic, it would normally be expected that some hydrogen evolution will proceed during indium and gallium electrodeposition. However, hydrogen evolution is suppressed by adding sulfinic or sulfonic compounds (e.g., sulfinic acid, sulfonic acid, benzene sulfonic acid, benzene sulfinic acid, benzene sulfonic compounds and/or benzene sulfinic compounds) to the methanesulfonic acid solution and other organic compounds containing nitrogen. The methanesulfonic acid/water based chemistry allows, enhances or assists in dissolution of one or more of the copper sulfate, the cupric sulfate, the indium sulfate, the gallium sulfate and the selenous acid. Use of organic additives (e.g., sulfinic, sulfonic, amines, and imidazoles, including polymers of sulfinic, sulfonic, amines, and imidazoles) in the acid chemistry (e.g., methanesulfonic acid and the water) substantially suppresses hydrogen evolution during electrodeposition. The third exemplary method of the invention is associated with, for example, the third aspect of the invention described above.

A solar cell (e.g., a thin film solar cell) may be formed to include one or more semiconductors formed according the third exemplary method.

A fourth exemplary method, according to an embodiment of the invention, comprises CIGS, CIS or CGS electrodeposition performed from an aqueous basic solution containing 2 M sodium hydroxide (NaOH) in water. The aqueous basic solution may, for example, be maintained at, a pH higher than about 8 (e.g., a pH of about 10 or higher). The solution having a pH higher than about 8 may be high enough to dissolve the component compounds containing copper, indium and gallium. 10 mM of cupric sulfate (CuSO₄), 50 mM indium sulfate (In₂(SO₄)₃), 50 mM of gallium sulfate (Ga₂(SO₄)₃) and 50 mM of selenous acid (H₂SeO₃) are dissolved in the basic solution. Sorbitol can be added as a grain refiner at concentrations from 50 mM to 1.0 M. The basic solution of the sodium hydroxide and water provides a pH high enough to assist in the dissolution of one or more of the cupric sulfate, the indium sulfate, the gallium sulfate and the selenous acid. The fourth exemplary method of the invention is associated with, for example, the fourth aspect of the invention described above.

A solar cell (e.g., a thin film solar cell) may be formed to include one or more semiconductors formed according the fourth exemplary method.

One or more semiconductors (e.g., the first semiconductor layer 140) comprised in a solar cell may be formed according to method of the invention (e.g., method 200). Additional steps may be included in forming a solar cell, for example, the formation of other layers of the solar cell (e.g., layers 110, 130, 150 and 160 of the solar cell illustrated in FIG. 1). The formation of one or more other layers of a solar cell may comprise, for example, deposition by vacuum-based evaporation, sputtering or a chemical bath. By way of example only, a semiconductor layer comprising CdS (e.g., the second semiconductor layer 130) may be formed by deposition using a chemical bath.

The formation of the first semiconductor layer 140 may comprise additional steps, besides electrodeposition of semiconductor layer 140, for example, annealing the first semiconductor layer 140, after the electrodeposition of the first semiconductor layer 140, at, for example, about 800° C. and in an atmosphere comprising Nitrogen, selenium or sulfur.

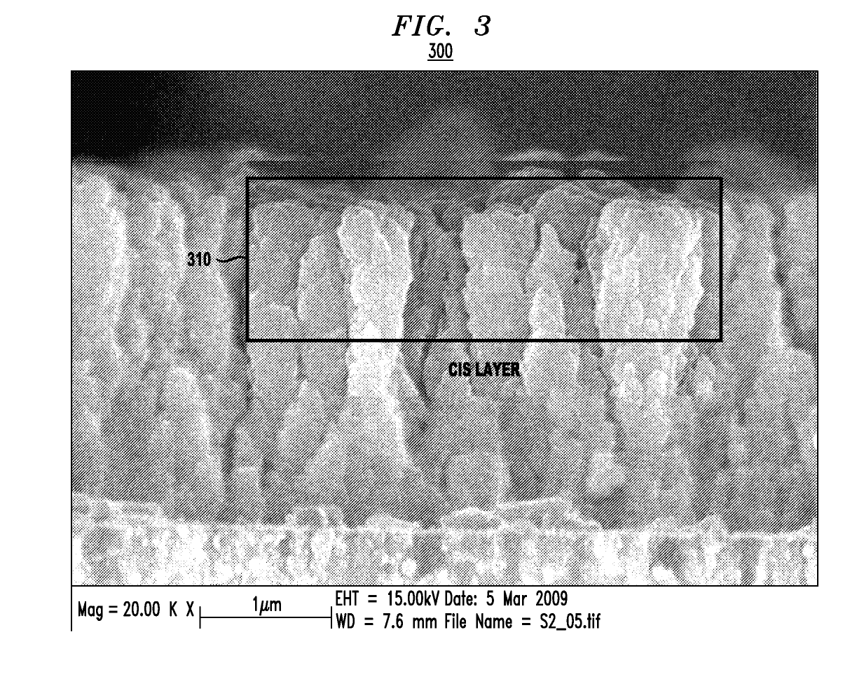

FIG. 3 is a scanning electron microscope image 300 of a semiconductor layer (e.g., the first semiconductor layer 140) formed according to an embodiment of the invention. The portion of the image 310 shows a CIS layer deposited from a solution containing 5 mM cupric sulfate, 10 mM selenous oxide, 15 mM indium sulfate, 15 mM gallium sulfate at 75° C. by applying −1.3 V vs. Ag/AgACl. The deposit was annealed at 550° C. in nitrogen (N₂) for 20 minutes. XRD (X-ray diffraction) spectra of the deposit that is shown in FIG. 3 demonstrated that the CuInSe₂ compound formed is highly crystalline and that no binary compounds such as CₓSe, CuSe or In₂Se₃ are formed.

It will be appreciated and should be understood that the exemplary embodiments of the invention described above can be implemented in a number of different fashions. Given the teachings of the invention provided herein, one of ordinary skill in the related art will be able to contemplate other implementations of the invention. Indeed, although illustrative embodiments of the present invention have been described herein with reference to the accompanying drawings, it is to be understood that the invention is not limited to those precise embodiments, and that various other changes and modifications may be made by one skilled in the art without departing from the scope or spirit of the invention.

What is claimed is:

1. A method of forming a photovoltaic device comprising a semiconductor layer, the method comprising:
forming the semiconductor layer by electrodeposition from an electrolyte solution, the electrolyte solution comprising: (i) copper; (ii) indium; (iii) gallium; (iv) selenous acid (H₂SeO₃); and (v) water.

2. The method of claim 1, wherein the electrolyte solution further comprises at least one of: (i) a cupric salt comprising the copper; (ii) an indium salt comprising the indium; and (iii) a gallium salt comprising the gallium.

3. The method of claim 2, wherein the cupric salt is cupric sulfate; wherein the indium salt is at least one of: indium sulfate, indium chloride, indium bromide, indium iodide, indium nitrate and indium perchlorate; and wherein the gallium salt is at least one of: gallium sulfate, gallium chloride, gallium bromide, gallium iodide, gallium nitrate and gallium perchlorate.

4. The method of claim 1, wherein a pH of the electrolyte solution is at least one of: (i) approximately 2.5, (ii) lower than approximately 2.5, (iii) higher than approximately 9, and (iv) set by addition of sulfuric acid (H₂SO₄) to the electrolyte solution.

5. The method of claim 1, wherein the electrodeposition comprises application of a deposition current between a substrate upon which a material is being deposited and a reference electrode, wherein a magnitude of the current is from about 4.5 to about 20 milliampere per cm² of the deposited material.

6. The method of claim 1, wherein the electrolyte solution further comprises at least one of: (i) trisodium citrate (Na₃C₆H₅O₇); and (ii) within about ten percent of 0.2 moles of the trisodium citrate per the liter of the electrolyte solution.

7. The method of claim 1, wherein a temperature of the electrolyte solution is between about twenty-five and about ninety degrees Celsius.

8. The method of claim 1, wherein the electrolyte solution further comprises a solution of methanesulfonic acid (CH₃SO₃H) and water, and wherein at least one of a compound comprising the copper, a compound comprising the indium, a compound comprising the gallium and the selenous acid are dissolved in the electrolyte solution comprising the solution of the methanesulfonic acid (CH₃SO₃H) and the water.

9. The method of claim 1, wherein at least one of a compound comprising the copper, a compound comprising the indium, a compound comprising the gallium and the selenous acid are dissolved in a solution comprising sodium hydroxide (NaOH) and water.

10. The method of claim 9, wherein the solution of the sodium hydroxide and the water comprises within about ten percent of 2 moles of the sodium hydroxide per liter of the solution of the sodium hydroxide and the water.

11. The method of claim 9, wherein the solution of the sodium hydroxide and the water assists in dissolution of at least one of: the compound comprising the indium, the compound comprising the gallium and the selenous acid.

12. The method of claim 3, wherein the electrolyte solution comprises:
within about ten percent of 0.001 to 0.010 moles of the cupric sulfate per liter of the electrolyte solution;
within about ten percent of 0.005 to 0.050 moles of the indium sulfate per the liter of the electrolyte solution;
within about ten percent of 0.005 to 0.050 moles of the gallium sulfate per the liter of the electrolyte solution; and
within about ten percent of 0.005 to 0.050 moles of the selenous acid per the liter of the electrolyte solution.

13. The method of claim 1, wherein the electrodeposition comprises application of a deposition potential between a substrate upon which a material is being deposited and a reference electrode, wherein a magnitude of the potential is below approximately 1.0 volts, wherein the semiconductor layer comprises copper indium di-selenide comprising the copper and the indium, and wherein substantially all copper comprised in the semiconductor layer is comprised in the copper indium di-selenide.

14. The method of claim 1, wherein the electrodeposition comprises application of a deposition potential between a substrate upon which a material is being deposited and a reference electrode, wherein a magnitude of the potential is above approximately 900 millivolts, and wherein the semiconductor layer comprises copper indium gallium di-selenide comprising the copper, the indium and the gallium.

15. The method of claim 1, wherein the electrodeposition comprises application of a deposition potential between a substrate upon which a material is being deposited and a reference electrode;
wherein a formula CuInₓGa₍₁₋ₓ₎Se₂ represents a composition of a semiconductor compound comprised in the semiconductor layer;
wherein Cu represents the copper, In represents the indium, Ga represents the gallium, and Se represents selenium;
wherein if X equals 1, the semiconductor compound comprises copper indium de-selenide (CuInSe₂) comprising substantially all of the copper comprised in the semiconductor layer;
wherein if X equals 0, the semiconductor compound comprises copper gallium de-selenide (CuGaSe₂) comprising substantially all of the copper comprised in the semiconductor layer; and
wherein if X has a value between 0 and 1, the semiconductor compound comprises copper indium gallium di-selenide (CIGS) having a ratio of an amount of indium to an amount of gallium equal to a ratio of X to 1−X.

16. The method of claim 15, wherein X decreases as a magnitude of the deposition potential increases above about 900 millivolts.

17. The method of claim 8, wherein at least one of:
(i) the solution of the methanesulfonic acid and the water comprises within ten percent of one (1) mole of the methanesulfonic acid per liter of the solution of the methanesulfonic acid and the water; and
(ii) the solution of the methanesulfonic acid and the water assists in dissolution of at least one of the compound comprising the copper, the compound comprising the indium, the compound comprising the gallium and the selenous acid.

18. The method of claim 1, wherein forming of hydrogen is suppressed by adding one or more of: a sulfinic compound, a sulfonic compound, a sulfinic acid, a sulfonic acid, sodium monohydrogen phthalate, monosodium phosphate, glycine, barbital, mannitol, sorbitol, amines, imidazoles, polymers and other organic additive, to the electrolyte solution.

19. The method of claim 1, wherein the electrolyte solution further comprises sorbitol (C₆H₁₄O₆) at a concentration within a range of from about 50 one-thousands (0.050) of a mole of the sorbitol per liter of the electrolyte solution to about 1 mole of the sorbitol per liter of the electrolyte solution.

20. The method of claim 1, wherein the electrolyte solution further comprises a chelating agent.

21. A photovoltaic device comprising:
a semiconductor layer formed by electrodeposition from an electrolyte solution, the electrolyte solution comprising: (i) copper; (ii) indium; (iii) gallium; (iv) selenous acid (H₂SeO₃); and (v) water.

22. The photovoltaic device of claim 21, wherein the electrolyte solution further comprises at least one of: (i) a cupric salt comprising the copper; (ii) an indium salt comprising the indium; and (iii) a gallium salt comprising the gallium.

23. A method of forming a semiconductor compound, the method comprising:
electrodeposition from an electrolyte solution comprising: (i) copper; (ii) indium; (iii) gallium; (iv) selenous acid (H₂SeO₃); and (v) water.

24. The method of claim 23, wherein the electrolyte solution further comprises at least one of: (i) a cupric salt comprising the copper; (ii) an indium salt comprising the indium; and (iii) a gallium salt comprising the gallium.

25. A chemical solution comprising: (i) copper; (ii) indium; (iii) gallium; (iv) selenous acid (H₂SeO₃); and (v) water.
